(19) United States
(12) Patent Application Publication
(10) Pub. No.: US 2024/0206204 A1
(43) Pub. Date: Jun. 20, 2024

(54) DISPLAY PANEL

(71) Applicant: Wuhan China Star Optoelectronics Semiconductor Display Technology Co., Ltd., Wuhan, Hubei (CN)

(72) Inventors: Guoqi XIA, Wuhan, Hubei (CN); Mugyeom KIM, Wuhan, Hubei (CN)

(73) Assignee: Wuhan China Star Optoelectronics Semiconductor Display Technology Co., Ltd., Wuhan, Hubei (CN)

(21) Appl. No.: 17/781,055

(22) PCT Filed: May 25, 2022
(86) PCT No.: PCT/CN2022/094905

§ 371 Date: May 31, 2022

(30) Foreign Application Priority Data
Apr. 29, 2022 (CN) 202210474317.3

(51) Int. Cl. H10K 50/11; H10K 101/30; H10K 102/00

(52) U.S. Cl. CPC H10K 50/11; H10K 2101/30; H10K 2102/351

(57) ABSTRACT

A display panel includes a substrate, a first electrode, a light-emitting layer, and a second electrode. The first electrode is disposed on the substrate. The light-emitting layer is disposed on a surface of the first electrode away from the substrate. The light-emitting layer includes a light-emitting sublayer. A compressibility parameter of the light-emitting sublayer is greater than or equal to a first threshold, and the compressibility parameter is determined by an amount of deformation of the light-emitting sublayer under unit force.

### FIELD OF INVENTION

The present disclosure relates to the technical field of display, and particularly to a display panel.

### BACKGROUND

Organic light-emitting diode (OLED) display panels have advantages of self-luminescence, fast response, wide viewing angle, and so on, and have a very broad application prospect.

In structural designs of current OLED display panels, more consideration is given to an energy level arrangement of molecular orbitals of functional layers. Optimizing the energy level arrangement is mainly to optimize efficiency of OLED devices. However, efficiency is not a main factor limiting large-scale commercialization of blue phosphorescent OLED devices. The blue phosphorescent OLED devices are not widely used because service life of the blue phosphorescent OLED devices is generally short.

### SUMMARY OF DISCLOSURE

The present disclosure provides a display panel with improved service life.

The present disclosure provides a display panel comprising a substrate, a first electrode, a light-emitting layer, and a second electrode. The first electrode is disposed on the substrate. The light-emitting layer is disposed on a surface of the first electrode away from the substrate and comprises a hole injection sublayer, a hole transport sublayer, a light-emitting sublayer, an electron transport sublayer, and an electron injection sublayer stacked in sequence. The second electrode is disposed on a surface of the light-emitting layer away from the substrate. A compressibility parameter of the light-emitting sublayer is greater than or equal to a first threshold, and the compressibility parameter is determined by an amount of deformation of the light-emitting sublayer under unit force.

In an embodiment, the compressibility parameter is determined by an amount of thickness deformation of a force-bearing part of the light-emitting sublayer in a thickness direction of the light-emitting sublayer under unit force.

In an embodiment, the compressibility parameter is calculated by the following formula: X=ΔF/ΔH, wherein ΔF is a difference between different forces in the thickness direction of the light-emitting sublayer, and ΔH is a thickness difference of the force-bearing part of the light-emitting sublayer under different forces.

In an embodiment, the first threshold is −1.7, and the compressibility parameter of the light-emitting sublayer is less than 0.

In an embodiment, when the display panel is powered on, a ratio of an amount of size deformation of the light-emitting sublayer to an original size of the light-emitting sublayer is less than or equal to 5%.

In an embodiment, when the display panel is powered on, a ratio of an amount of thickness expansion of the light-emitting sublayer to an original thickness of the light-emitting sublayer is less than or equal to 5%.

In an embodiment, when the light-emitting sublayer is heated, a ratio of an amount of size deformation of the light-emitting sublayer to an original size of the light-emitting sublayer is less than or equal to 10%.

In an embodiment, when the light-emitting sublayer is heated, a ratio of an amount of thickness expansion of the light-emitting sublayer to an original thickness of the light-emitting sublayer is less than or equal to 10%.

In an embodiment, energy levels of highest occupied orbitals of the hole transport sublayer, the light-emitting sublayer, and the electron transport sublayer decrease sequentially, and energy levels of lowest unoccupied orbitals of the hole transport sublayer, the light-emitting sublayer, and the electron transport sublayer decrease sequentially.

In an embodiment, a difference between the energy levels of the highest occupied orbitals of the hole transport sublayer and the light-emitting sublayer is less than or equal to 0.2 eV, and a difference between the energy levels of the lowest unoccupied orbitals of the electron transport sublayer and the light-emitting sublayer is less than or equal to 0.2 eV.

In an embodiment, the light-emitting sublayer comprises a blue phosphorescent light-emitting material or a blue fluorescent light-emitting material.

In an embodiment, the light-emitting sublayer comprises a red phosphorescent light-emitting material or a red fluorescent light-emitting material.

In an embodiment, the light-emitting sublayer comprises a green phosphorescent light-emitting material or a green fluorescent light-emitting material.

In an embodiment, the first electrode is an anode electrode, and the second electrode is a cathode electrode.

The present disclosure further provides a display panel comprising a substrate, a first electrode, a light-emitting layer, and a second electrode. The first electrode is disposed on the substrate. The light-emitting layer is disposed on a surface of the first electrode away from the substrate and comprises a hole injection sublayer, a hole transport sublayer, a light-emitting sublayer, an electron transport sublayer, and an electron injection sublayer stacked in sequence. The second electrode is disposed on a surface of the light-emitting layer away from the substrate. A compressibility parameter of the light-emitting sublayer is greater than or equal to a first threshold. The compressibility parameter is determined by an amount of deformation of the light-emitting sublayer under unit force, and the compressibility parameter is determined by an atomic force microscope.

In an embodiment, the compressibility parameter is determined by an amount of thickness deformation of a force-bearing part of the light-emitting sublayer in a thickness direction of the light-emitting sublayer under unit force.

In an embodiment, the compressibility parameter is calculated by the following formula: X=ΔF/ΔH, wherein ΔF is a difference between different forces in the thickness direction of the light-emitting sublayer, and ΔH is a thickness difference of the force-bearing part of the light-emitting sublayer under different forces.

In an embodiment, the first threshold is −1.7, and the compressibility parameter of the light-emitting sublayer is less than 0.

In an embodiment, when the display panel is powered on, a ratio of an amount of thickness expansion of the light-emitting sublayer to an original thickness of the light-emitting sublayer is less than or equal to 5%.

In an embodiment, when the light-emitting sublayer is heated, a ratio of an amount of thickness expansion of the light-emitting sublayer to an original thickness of the light-emitting sublayer is less than or equal to 10%.

The present disclosure provides a display panel, which comprises a substrate, a first electrode, a light-emitting layer, and a second electrode. The first electrode is disposed on the substrate. The light-emitting layer is disposed on a surface of the first electrode away from the substrate. The light-emitting layer comprises a hole injection sublayer, a hole transport sublayer, a light-emitting sublayer, an electron transport sublayer, and an electron injection sublayer that are sequentially stacked on the first electrode. A compressibility parameter of the light-emitting sublayer is greater than or equal to a first threshold, and the compressibility parameter is determined by an amount of deformation of the light-emitting sublayer under unit force. The inventors of the present application found that when the compressibility parameter of the light-emitting sublayer is greater than or equal to the first threshold, the compressibility parameter is positively correlated with service life of the display panel. The greater the compressibility parameter, the higher the compressibility, and the longer the service life of the display panel.

### BRIEF DESCRIPTION OF DRAWINGS

In order to more clearly illustrate technical solutions in embodiments of the present disclosure, a brief description of accompanying drawings used in a description of the embodiments will be given below. Obviously, the accompanying drawings in the following description are merely some embodiments of the present disclosure. For those skilled in the art, other drawings may be obtained from these accompanying drawings without creative labor.

FIG. 1 is a schematic structural diagram of a display panel according to an embodiment of the present disclosure.

FIG. 2 is a schematic diagram illustrating a detection of a compressibility parameter of a light-emitting sublayer by an atomic force microscope according to an embodiment of the present disclosure.

FIG. 3 is a schematic diagram showing a fitted linear relationship of the light-emitting sublayer whose host material is N,N′-dicarbazolyl-3,5-benzene (mCP) according to an embodiment of the present disclosure.

FIG. 4 shows chemical structural formulas of organic light-emitting materials according to an embodiment of the present disclosure.

FIG. 5 is a schematic diagram of an energy level arrangement of the display panel according to an embodiment of the present disclosure.

### DETAILED DESCRIPTION

In order to make purposes, technical solutions, and advantages of the present application clearer, the present application will be further described in detail below in conjunction with accompanying drawings. In the accompanying drawings, same reference numerals indicate same elements. The following description of specific embodiments of the present application should not be regarded as limitations of other specific embodiments not described in detail in the present application. The term “embodiment” used in the present disclosure means an example, an instance, or an illustration.

In the description of the present disclosure, it should be understood that location or position relationships indicated by terms, such as “center”, “longitudinal”, “transverse”, “length”, “width”, “thickness”, “up”, “down”, “front”, “rear”, “left”, “right”, “vertical”, “horizontal”, “top”, “bottom”, “within”, “outside”, “clockwise”, and “counterclockwise”, are location or position relationships based on illustration of the accompanying drawings, are merely used for describing the present disclosure and simplifying the description instead of indicating or implying the indicated apparatuses or elements should have specified locations or be constructed and operated according to specified locations, and therefore, should not be intercepted as limitations to the present disclosure. terms such as “first” and “second” are used merely for the purpose of description, but shall not be construed as indicating or implying relative importance or implicitly indicating a number of the indicated technical feature. Hence, the feature defined with “first” and “second” may explicitly or implicitly includes one or more of this feature. In the description of the present disclosure, a term “a plurality of” means “two or more” unless otherwise specifically limited.

The present disclosure provides a display panel, which will be described in detail below. It should be noted that a description order of the following embodiments is not intended to limit a preferred order of the embodiments.

The display panel provided by the present disclosure will be described in detail below through specific embodiments.

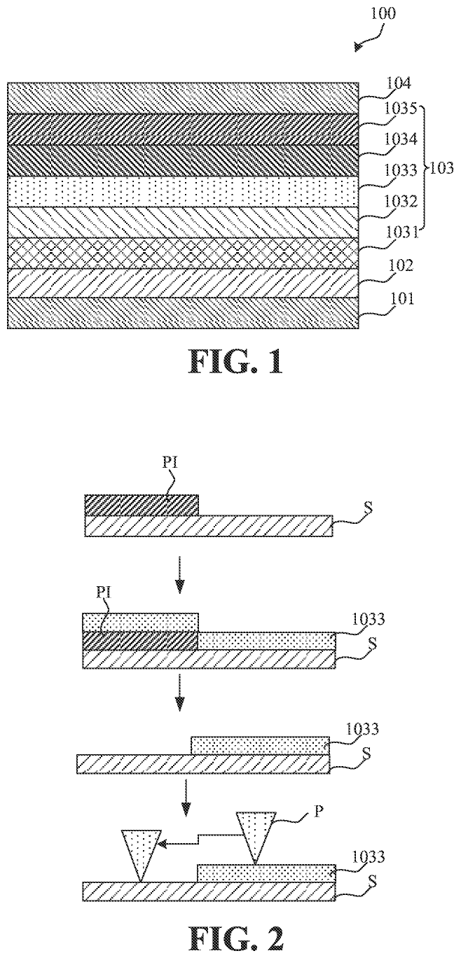

Please refer to FIG. 1, which is a schematic structural diagram of a display panel according to an embodiment of the present disclosure. The present disclosure provides a display panel 100 comprising a substrate 101, a first electrode 102, a light-emitting layer 103, and a second electrode 104. The first electrode 102 is disposed on the substrate 101. The light-emitting layer 103 is disposed on a surface of the first electrode 102 away from the substrate 101. The light-emitting layer 103 comprises a hole injection sublayer 1031, a hole transport sublayer 1032, a light-emitting sublayer 1033, an electron transport sublayer 1034, and an electron injection sublayer 1035 that are sequentially stacked on the first electrode 102. A compressibility parameter of the light-emitting sublayer 1033 is greater than or equal to a first threshold, and the compressibility parameter is determined by an amount of deformation of the film under unit force.

The inventors of the present application found that when the compressibility parameter of the light-emitting sublayer 1033 is greater than or equal to the first threshold, the compressibility parameter is positively correlated with service life of the display panel 100. The greater the compressibility parameter, the higher the compressibility, and the longer the service life of the display panel 100.

It should be understood that in this embodiment, the compressibility parameter is related to the compressibility. The higher the compressibility, the greater the compressibility parameter, and the longer the service life of the display panel 100.

It should be noted that in this embodiment, the unit force comprises, but is not limited to, a force applied to the light-emitting sublayer 1033. The unit force refers to a force applied to a minimum measurement unit of the light-emitting sublayer 1033, for example, 1N, 2N, 5N, 10N, and the like.

It should be noted that in this embodiment, the amount of the deformation of the film comprises, but is not limited to, an amount of thickness deformation of the film.

In some embodiments, the compressibility parameter is determined by an amount of thickness deformation of a force-bearing part of the film in a thickness direction of the film under unit force. Specifically, the compressibility parameter may be calculated by the following formula: X=ΔF/ΔH, wherein X is the compressibility parameter, ΔF is a difference between different forces in the thickness direction of the film, and ΔH is a thickness difference of the force-bearing part of the film under different forces. 0>X>−1.7 N/cm.

That is, the first threshold is −1.7. When the compressibility parameter is greater than or equal to −1.7 and is less than 0, the greater the compressibility parameter, the higher the compressibility of the film, and the longer the service life of the display panel 100.

ΔF is a difference between two different forces applied to one same force-bearing part, and ΔH is a difference between two thicknesses corresponding to the two different forces. Alternatively, ΔF is a difference between two different forces applied to two different force-bearing parts, and ΔH is a difference between two thicknesses corresponding to the two different forces.

It should be noted that in this embodiment, the larger the unit force on the film, the smaller the thickness of the film.

In the present application, the compressibility parameter of the light-emitting sublayer 1033 may be detected by using an atomic force microscope. Under a detection of the atomic force microscope, a thickness of the light-emitting sublayer 1033 has a linear relationship with a force applied on the light-emitting sublayer 1033 by a probe of the atomic force microscope. A slope of the linear relationship is the compressibility parameter.

Specifically, the light-emitting sublayer 1033 is detected by an atomic force microscope, and then a linear relationship between the thickness of the light-emitting sublayer 1033 and the force applied by the probe of the atomic force microscope to the light-emitting sublayer 1033 is established. The greater the slope of the linear relationship is, the higher the compressibility of the light-emitting sublayer 1033 is, and the longer the service life of the display panel 100 is.

Please refer to FIG. 2, which is a schematic diagram illustrating a detection of a compressibility parameter of a light-emitting sublayer by an atomic force microscope according to an embodiment of the present disclosure. Measurement of the compressibility parameter of the light-emitting sublayer 1033 specifically comprises detecting the light-emitting sublayer 1033 with an atomic force microscope.

A process of detecting the light-emitting sublayer 1033 by the atomic force microscope may comprise: disposing the light-emitting sublayer 1033 on a substrate S, and detecting a relative thickness of the light-emitting sublayer 1033 by a probe P. The disposing the light-emitting sublayer 1033 on the substrate S comprises: disposing a polyimide layer PI on the substrate S, wherein the polyimide layer PI covers a part of the substrate S; vapor-depositing the light-emitting sublayer 1033 on the substrate S, wherein the light-emitting sublayer 1033 covers the polyimide layer PI and the substrate S; and tearing off the polyimide layer PI, thereby forming the light-emitting sublayer 1033 on the substrate S. In this embodiment, the light-emitting sublayer 1033 only covers a part of the substrate S to form a height difference, which is used to measure the relative thickness of the light-emitting sublayer 1033. The detecting the relative thickness of the light-emitting sublayer 1033 by the probe P comprises the following steps. First, a point of the light-emitting sublayer 1033 is randomly selected, the probe P applies a first force to the point, and the probe P applies the first force to the substrate S, thereby measuring a first relative thickness of the light-emitting sublayer 1033. Then, another point of the light-emitting sublayer 1033 is randomly selected, the probe P applies a second force to the another point, and the probe P applies the second force to the substrate S, thereby measuring a second relative thickness of the light-emitting sublayer 1033. The above steps are repeated to measure a third relative thickness of the light-emitting sublayer 1033 with a third force, measure a fourth relative thickness of the light-emitting layer b with a fourth force, and measure an N-th relative thickness of the light-emitting sublayer 1033 with an N-th force. Finally, the forces applied by the probe to the light-emitting sublayer 1033 are taken as abscissas, and the thicknesses of the light-emitting sublayer 1033 are taken as ordinates, a slope of a fitted linear relationship is the compressibility parameter of the light-emitting sublayer 1033. The larger the slope is, the larger the compressibility of the light-emitting sublayer 1033 is, and the longer the service life of the display panel 100 is.

In this embodiment, the thickness of the light-emitting sublayer 1033 decreases as the force applied by the probe P to the light-emitting sublayer 1033 increases. The greater the force applied by the probe P to the light-emitting sublayer 1033 is, the smaller the thickness of the light-emitting sublayer 1033 is. In this embodiment, the forces applied by the probe P to the light-emitting sublayer 1033 are taken as abscissas, and the thicknesses of the light-emitting sublayer 1033 are taken as ordinates, thereby obtaining a fitted linear relationship.

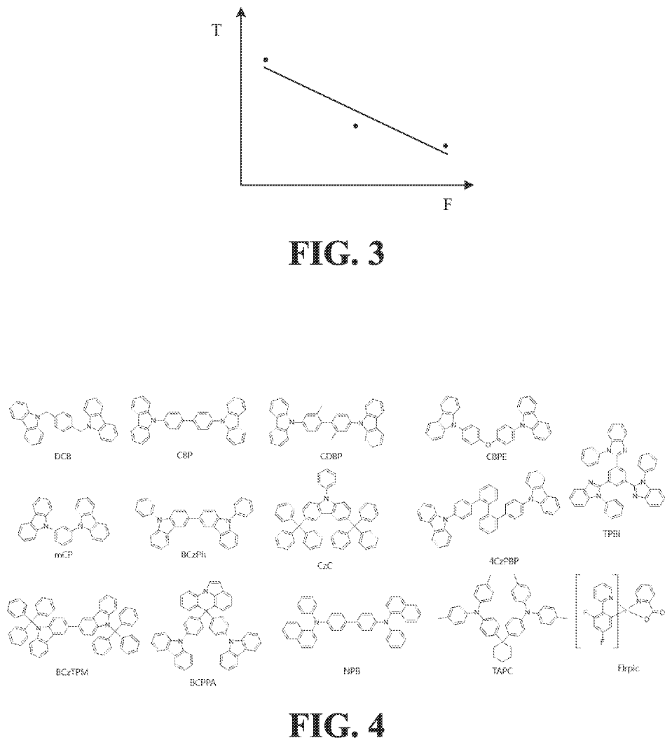

Please refer to FIG. 3, which is a schematic diagram showing a fitted linear relationship of the light-emitting sublayer whose host material is N,N′-dicarbazolyl-3,5-benzene (mCP) according to an embodiment of the present disclosure. In this embodiment, forces (F) applied by a probe to the light-emitting sublayer 1033 are taken as abscissas, and thicknesses (T) of the light-emitting sublayer 1033 are taken as ordinates, and a slope of a fitted linear relationship is taken as the compressibility parameter of the light-emitting sublayer 1033, wherein the slope is −1.69.

Specifically, in this embodiment, each of ten different organic light-emitting materials is used as the host material of the light-emitting sublayer 1033, and compressibility and light-emitting performance of the corresponding light-emitting sublayer 1033 are detected. Please refer to FIG. 4, which shows chemical structural formulas of organic light-emitting materials according to an embodiment of the present disclosure. The organic light-emitting materials comprise DCB, CBP, CDBP, CBPE, mCP, BCzph, CzC, 4CzPBP, TPBi, BCzTPM, BCPPA, NPB, TAPC, and Firpic.

Please refer to Table 1, which shows compressibility parameters of light-emitting sublayers whose host materials are the ten different organic light-emitting materials and performance test results of corresponding display panels.

TABLE 1

| Organic | | | | | |
|---|---|---|---|---|---|
| light-emitting | | | Voltage | EQE | LT95 |
| material | Slope | EL peak | at J10 | (%) | at 100 cd/m² |
| DCB | −2.07 | 471 | 3.62 | 18.7 | 20 |
| CBP | −1.95 | 472 | 3.61 | 18.6 | 31 |
| CDBP | −1.88 | 472 | 3.62 | 19.1 | 43 |
| CBPE | −1.74 | 472 | 3.59 | 19.0 | 55 |
| mCP | −1.69 | 471 | 3.60 | 19.2 | 67 |
| BCzPh | −1.55 | 473 | 3.59 | 19.3 | 89 |
| CzC | −1.43 | 473 | 3.60 | 19.7 | 112 |
| 4CzPBP | −1.39 | 471 | 3.59 | 20.1 | 129 |
| BCzTPM | −1.26 | 472 | 3.58 | 19.9 | 137 |
| BCPPA | −1.17 | 471 | 3.58 | 20.3 | 146 |

Please refer to Table 1. the light-emitting sublayers 1033 and the display panels 100 made by using different organic light-emitting materials as host materials under same conditions are detected by an atomic force microscope, and the greater the slope, the greater the compressibility of the light-emitting sublayer 1033. As the compressibility of the light-emitting sublayer 1033 increases, an impact on voltage and electroluminescence peak (EL Peak) is small, an external quantum efficiency (EQE) is slightly improved, and service life is significantly improved. It is proved that the higher the compressibility of the light-emitting sublayer 1033 is, the better the light-emitting performance of blue phosphorescent materials.

It should be noted that the slope is measured by the aforementioned method of detecting the light-emitting sublayer 1033 by the atomic force microscope.

When the slope is greater than or equal to −1.7, the service life of the display panel 100 is significantly improved. The first threshold may also be selected from −1.65, −1.6, −1.55, −1.5, −1.45, −1.4, −1.35, −1.3, −1.25, −1.2, −1.15, and so on.

Compared with red phosphorescent materials and green phosphorescent materials, service life of blue phosphorescent materials is particularly short, which reduces the service life and reliability of the display panel 100. In this embodiment, taking a blue phosphorescent material as an example, by increasing compressibility of a film made of the blue phosphorescent material, the service life and reliability of the display panel 100 made of the blue phosphorescent material are improved, thereby improving market competitiveness.

In some embodiments, the light-emitting sublayer 1033 comprises, but is not limited to, a blue phosphorescent light-emitting material or a blue fluorescent light-emitting material. The light-emitting sublayer 1033 may also comprise a red phosphorescent light-emitting material, a green phosphorescent light-emitting material, a red fluorescent light-emitting material, or a green fluorescent light-emitting material.

In this embodiment, the light-emitting sublayer 1033 is detected by the atomic force microscope, and a linear relationship between the thickness of the light-emitting sublayer 1033 and the force applied by the probe of the atomic force microscope to the light-emitting sublayer 1033 is established. The greater the slope of the linear relationship is, the greater the compressibility parameter of the film is, the greater the compressibility of the light-emitting sublayer 1033 is, and the longer the service life of the display panel 100 is. The slope of the linear relationship is the compressibility parameter of the light-emitting sublayer 1033. In this embodiment, when the compressibility parameter of the light-emitting sublayer 1033 is greater than or equal to the first threshold, the service life of the display panel 100 is significantly improved.

In some embodiments of the present application, a film quality of the light-emitting sublayer 1033 may also be evaluated by an amount of size deformation of the light-emitting sublayer 1033.

In order to further evaluate the film quality of the light-emitting sublayer 1033, when the display panel 100 is powered on, a ratio of an amount of size deformation of the light-emitting sublayer 1033 to an original size of the light-emitting sublayer 1033 is less than or equal to 5%.

It should be noted that the amount of size deformation of the light-emitting sublayer 1033 comprises, but is not limited to, an amount of thickness expansion of the light-emitting sublayer 1033.

In some embodiments, when the display panel 100 is powered on, a ratio of the amount of the thickness expansion of the light-emitting sublayer 1033 to an original thickness of the light-emitting sublayer 1033 is less than or equal to 5%.

For example, the light-emitting sublayer 1033 has a first thickness a before power-on. After the display panel 100 emits light with a preset brightness for a preset working time, the light-emitting sublayer 1033 has a second thickness b. A thickness expansion amount θ1 of the second thickness b and the first thickness a is less than or equal to 5%, wherein ω1=[(b−a)/a]*100%.

In some embodiments, the preset brightness may be 100 nits, and the preset working time may be 1 hour. Specifically, after the display panel 100 emits light with a brightness of 100 nits for 1 hour, a thickness before emitting light and a thickness after emitting light are measured by using an interferometer.

In some embodiments, evaluation may also be performed by heating the display panel 100 and measuring a thickness of the display panel 100 before heating and a thickness of the display panel 100 after heating.

In some embodiments, when the light-emitting sublayer 1033 is heated, a ratio of an amount of size deformation of the light-emitting sublayer 1033 to an original size of the light-emitting sublayer 1033 is less than or equal to 10%.

In some embodiments, the light-emitting sublayer 1033 is heated, a ratio of an amount of thickness expansion of the light-emitting sublayer 1033 to an original thickness of the light-emitting sublayer 1033 is less than or equal to 10%.

Specifically, the light-emitting sublayer 1033 before heating has a first thickness a. After the display panel 100 is heated at a preset temperature for a preset working time, the light-emitting sublayer has a second thickness c. A thickness expansion amount ω2 of the second thickness c and the first thickness a is less than or equal to 10%, wherein ω2=[(c−a)/a]*100%.

The preset temperature may be 100 degrees Celsius, and the preset working time may be 1 hour. Specifically, the display panel 100 is heated to 100 degrees Celsius and kept at 100 degrees Celsius for 1 hour. A thickness of the display panel 100 after heating is measured by using an interferometer.

Please refer to Table 2, which shows the thickness expansion amount of the light-emitting sublayer when the display panel 100 is powered on or heated.

TABLE 2

| Organic light-emitting material | ω1 | ω2 |
|---|---|---|
| DCB | 7.4% | 14.5% |
| CBP | 7.0% | 13.7% |
| CDBP | 6.5% | 12.4% |
| CBPE | 5.7% | 11.5% |
| mCP | 5.1% | 10.4% |
| BCzPh | 4.6% | 10.1% |
| CzC | 4.1% | 9.2% |
| 4CzPBP | 3.9% | 8.7% |
| BCzTPM | 3.6% | 7.9% |
| BCPPA | 3.2% | 7.2% |

Please refer to Table 2. The thicknesses of the light-emitting sublayer 1033 before and after heating are measured by the interferometer, and the thickness expansion amount before and after heating is calculated. The smaller the thickness expansion amount is, the better the film quality of the light-emitting sublayer 1033 is, the higher the compressibility of the light-emitting sublayer 1033 is, the better the performance of the display panel 100 is, and the smaller the thickness expansion amount after heating. It should be noted that in practical applications, the maximum value of ω1 may be selected as 5%, 4.5%, 4%, 3.5%, 3%, or the like, and the maximum value of ω2 may be selected as 10%, 9.5%, 9%, 8.5%, 8%, 7.5%, 7%, or the like.

It can be seen from Table 1 and Table 2 that the higher the compressibility parameter of the light-emitting sublayer, the higher the compressibility, the better the light-emitting performance, the smaller the thickness expansion amount after heating, and the longer the service life of the display panel 100.

In the embodiments of the present application, the film quality of the light-emitting sublayer 1033 of the display panel 100 is evaluated from two aspects, comprising: evaluating the compressibility of the light-emitting sublayer 1033, and evaluating the thickness of the light-emitting sublayer 1033 in the display panel 100 before and after heating. The evaluation of the film quality of the light-emitting sublayer 1033 of the display panel 100 from two aspects shows the following. Under the detection of the atomic force microscope, the larger the slope is, the greater the compressibility parameter of the light-emitting sublayer 1033 is, and the greater the compressibility of the light-emitting sublayer 1033 is. As the compressibility of the light-emitting sublayer 1033 increases, an impact on voltage and electroluminescence peak (EL Peak) is small, an external quantum efficiency (EQE) is slightly improved, and service life is significantly improved. It is proved that the higher the compressibility of the light-emitting sublayer 1033 is, the better the light-emitting performance of blue phosphorescent materials. The thicknesses of the display panel 100 before and after heating are measured by the interferometer, and the thickness expansion amount of the light-emitting sublayer 1033 before and after heating is calculated. The smaller the thickness expansion amount of the light-emitting sublayer 1033 is, the better the film quality of the light-emitting sublayer 1033 is, the higher the compressibility of the light-emitting sublayer is, the better the light-emitting performance, and the smaller the thickness expansion amount after heating.

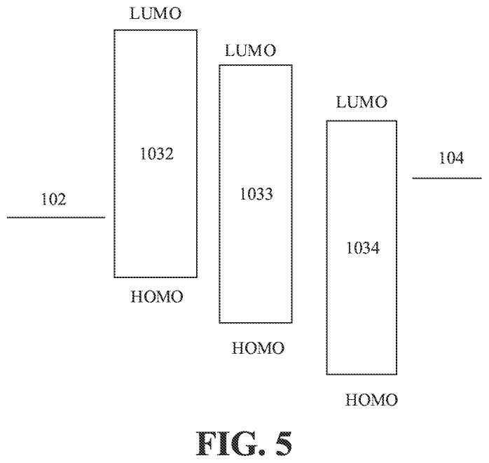

Please refer to FIG. 5, which is a schematic diagram of an energy level arrangement of the display panel according to an embodiment of the present disclosure. In some embodiments, energy levels of lowest unoccupied orbitals of the hole transport sublayer 1032, the light-emitting sublayer 1033, and the electron transport sublayer 1034 decrease sequentially, and energy levels of highest occupied orbitals of the hole transport sublayer 1032, the light-emitting sublayer 1033, and the electron transport sublayer 1034 decrease sequentially.

In this embodiment, the lowest unoccupied orbital energy levels and the highest occupied orbital energy levels of the hole transport sublayer 1032, the light-emitting sublayer 1033, and the electron transport sublayer 1034 decrease sequentially. That is, the highest occupied orbital energy levels and the lowest unoccupied orbital energy levels of materials of adjacent organic layers are arranged in steps. Such an arrangement is beneficial to balanced injection and transport of carriers, and reduces energy level potential barriers, thereby improving a light-emitting efficiency of the display panel 100 and obtaining optimal device performance.

It should be noted that the highest occupied orbital refers to a molecular orbital with the highest energy among molecular orbitals occupied by electrons, which is also called a highest occupied molecular orbital. Among molecular orbitals not occupied by electrons, a molecular orbital with the lowest energy is called the lowest unoccupied orbital.

In some embodiments, electrons and holes may be injected in a balanced ratio of 1:1 to achieve efficient utilization of electrons and holes.

In order to reduce a potential barrier of hole injection from the first electrode 102, so that holes can be effectively injected from the first electrode 102 into the display panel 100, a transport rate of holes is generally greater than a transport rate of electrons. In order for recombination of electrons and holes injected from the electrodes to occur in the light emitting sublayer 1033, energy level structures of the hole transport sublayer 1032 and the light emitting sublayer 1033 are matched, and the transport rate of holes is matched. In order to reduce a potential barrier of electron injection from the second electrode 104, so that electrons can be effectively injected from the second electrode 104 into the display panel 100, when selecting a material of the electron injection sublayer 1035, in order to effectively inject electrons from the second electrode 104 into the display panel 100, the potential barrier of hole injection from the anode is lowered, so that holes can be efficiently injected from the anode into the OLED device. Therefore, when selecting the material of the electron injection layer, an energy level matching of the material and a material of the second electrode 104 needs to be considered.

In some embodiments, lowest unoccupied orbital energy levels and highest occupied orbital energy levels of the hole injection sublayer 1031, the hole transport sublayer 1032, the light-emitting sublayer 1033, the electron transport sublayer 1034, and the electron injection sublayer 1035 decrease sequentially. Such an arrangement is beneficial to balanced injection and transport of carriers, and reduces energy level potential barriers, thereby improving light-emitting efficiency of the display panel 100 and obtaining optimal device performance.

In some embodiments, a difference between the highest occupied orbital energy level of the hole transport sublayer 1032 and the highest occupied orbital energy level of the light-emitting sublayer 1033 is less than or equal to 0.2 eV, and a difference between the lowest unoccupied orbital energy level of the electron transport sublayer 1034 and the lowest unoccupied orbital energy level of the light-emitting sublayer 1033 is less than or equal to 0.2 eV, thereby reducing potential barriers between adjacent organic layers and further improving the light-emitting efficiency of the display panel 100.

Specifically, the difference between the highest occupied orbital energy level of the hole transport sublayer 1032 and the highest occupied orbital energy level of the light-emitting sublayer 1033 may be any one of 0.05 eV, 0.08 eV, 0.12 eV, 0.15 eV, 0.18 eV, and 0.2 eV, and the difference between the lowest unoccupied orbital energy level of the electron transport sublayer 1034 and the lowest unoccupied orbital energy level of the light-emitting sublayer 1033 may be any one of 0.05 eV, 0.08 eV, 0.12 eV, 0.15 eV, 0.18 eV, and 0.2 eV, thereby reducing the potential barriers between the adjacent organic layers and further improving the light-emitting efficiency of the display panel 100.

In some embodiments, the display panel 100 further comprises a thin film transistor layer. The thin film transistor layer is disposed on the substrate 101. The thin film transistor layer is configured to drive the display panel 100 to emit light.

In some embodiments, the first electrode 102 is an anode electrode. A material of the first electrode 102 comprises indium tin oxide and silver, and may specifically be a three-layer structure of indium tin oxide, silver, and indium tin oxide. The second electrode 104 is a cathode electrode. A material of the second electrode 104 is magnesium-silver alloy.

Correspondingly, the present disclosure further provides a method for manufacturing a display panel, which comprises the following steps.

Step B001: providing a first electrode, wherein the first electrode comprises indium tin oxide and silver.

After step B001, step B002: forming a hole injection sublayer and a hole transport sublayer on the first electrode in sequence. The hole transport sublayer may be made of N,N′-bis(1-naphthyl)-N,N′-diphenyl-1,1′-biphenyl-4-4′-diamine (NPB). The hole transport sublayer has a thickness of 30 nm to 60 nm. In a specific embodiment, the hole transport sublayer may have a thickness of 45 nm.

Step B003: forming an electron blocking layer on the hole transport sublayer. The electron blocking layer may be made of 4,4′-cyclohexylbis[N,N-bis(4-methylphenyl)aniline](TAPC). The electron blocking layer may have a thickness of 2 nm to 10 nm. In a specific embodiment, the electron blocking layer may have a thickness of 5 nm.

Step B004: forming a light-emitting sublayer on the electron blocking layer. The light-emitting sublayer comprises an organic light-emitting material, and a concentration of the organic light-emitting material doped in the light-emitting sublayer is less than 2%. A vapor-depositing rate of the light-emitting sublayer is less than or equal to 1.5 Å/second. In an embodiment, the vapor-depositing rate of the light-emitting sublayer is 1.0 Å/second. A host material of the organic light-emitting material may be at least one of DCB, CBP, CDBP, CBPE, mCP, BCzph, CzC, 4CzPBP, TPBi, BCzTPM, BCPPA, NPB, TAPC, and Firpic, whose chemical structural formulas are shown in FIG. 4. The light-emitting sublayer may have a thickness of 10 nm to 30 nm. In a specific embodiment, the light emitting sublayer may have a thickness of 20 nm.

Step B005: forming an electron transport sublayer and an electron injection sublayer in sequence on a surface of the light emitting sublayer away from the first electrode. The electron transport sublayer may be made of 1,3,5-tris(1-phenyl-1H-benzimidazol-2-yl)benzene (TPBi) The electron transport sublayer has a thickness of 20 nm to 40 nm. In a specific embodiment, the electron transport sublayer may have a thickness of 35 nm.

Step B006: vapor-depositing a second electrode on a surface of the electron injection sublayer away from the first electrode. A material of the second electrode may comprise a magnesium-silver alloy. A vapor-depositing rate of the second electrode is less than or equal to 3 Å/second. In an embodiment, the vapor-depositing rate of the second electrode may be 2 Å/second. The second electrode has a thickness of 50 nm to 150 nm. For example, the second electrode may have a thickness of 100 nm.

The present application has been described in the above preferred embodiments, but the preferred embodiments are not intended to limit the scope of the present application. Those skilled in the art may make various changes and modifications without departing from the scope of the present application. The scope of the present application is determined by claims.

1. A display panel, comprising:
a substrate,
a first electrode disposed on the substrate;
a light-emitting layer disposed on a surface of the first electrode away from the substrate and comprising a hole injection sublayer, a hole transport sublayer, a light-emitting sublayer, an electron transport sublayer, and an electron injection sublayer stacked in sequence; and
a second electrode disposed on a surface of the light-emitting layer away from the substrate;
wherein a compressibility parameter of the light-emitting sublayer is greater than or equal to a first threshold, and the compressibility parameter is determined by an amount of deformation under unit force of the light-emitting sublayer.

2. The display panel according to claim 1, wherein the compressibility parameter is determined by an amount of thickness deformation of a force-bearing part of the light-emitting sublayer in a thickness direction of the light-emitting sublayer under unit force.

3. The display panel according to claim 2, wherein the compressibility parameter is calculated by the following formula:
X=ΔF/ΔH,
wherein ΔF is a difference between different forces in the thickness direction of the light-emitting sublayer, and ΔH is a thickness difference of the force-bearing part of the light-emitting sublayer under different forces.

4. The display panel according to claim 3, wherein the first threshold is −1.7, and the compressibility parameter of the light-emitting sublayer is less than 0.

5. The display panel according to claim 1, wherein when the display panel is powered on, a ratio of an amount of size deformation of the light-emitting sublayer to an original size of the light-emitting sublayer is less than or equal to 5%.

6. The display panel according to claim 5, wherein when the display panel is powered on, a ratio of an amount of thickness expansion of the light-emitting sublayer to an original thickness of the light-emitting sublayer is less than or equal to 5%.

7. The display panel according to claim 1, wherein when the light-emitting sublayer is heated, a ratio of an amount of size deformation of the light-emitting sublayer to an original size of the light-emitting sublayer is less than or equal to 10%.

8. The display panel according to claim 7, wherein when the light-emitting sublayer is heated, a ratio of an amount of thickness expansion of the light-emitting sublayer to an original thickness of the light-emitting sublayer is less than or equal to 10%.

9. The display panel according to claim 1, wherein energy levels of highest occupied orbitals of the hole transport sublayer, the light-emitting sublayer, and the electron transport sublayer decrease sequentially, and energy levels of lowest unoccupied orbitals of the hole transport sublayer, the light-emitting sublayer, and the electron transport sublayer decrease sequentially.

10. The display panel according to claim 9, wherein a difference between the energy levels of the highest occupied orbitals of the hole transport sublayer and the light-emitting sublayer is less than or equal to 0.2 eV, and a difference between the energy levels of the lowest unoccupied orbitals of the electron transport sublayer and the light-emitting sublayer is less than or equal to 0.2 eV.

11. The display panel according to claim 1, wherein the light-emitting sublayer comprises a blue phosphorescent light-emitting material or a blue fluorescent light-emitting material.

12. The display panel according to claim 1, wherein the light-emitting sublayer comprises a red phosphorescent light-emitting material or a red fluorescent light-emitting material.

13. The display panel according to claim 1, wherein the light-emitting sublayer comprises a green phosphorescent light-emitting material or a green fluorescent light-emitting material.

14. The display panel according to claim 1, wherein the first electrode is an anode electrode, and the second electrode is a cathode electrode.

15. A display panel, comprising:
a substrate,
a first electrode disposed on the substrate;
a light-emitting layer disposed on a surface of the first electrode away from the substrate and comprising a hole injection sublayer, a hole transport sublayer, a light-emitting sublayer, an electron transport sublayer, and an electron injection sublayer stacked in sequence; and
a second electrode disposed on a surface of the light-emitting layer away from the substrate;
wherein a compressibility parameter of the light-emitting sublayer is greater than or equal to a first threshold, the compressibility parameter is determined by an amount of deformation of the light-emitting sublayer under unit force, and the compressibility parameter is determined by atomic force microscopy.

16. The display panel according to claim 15, wherein the compressibility parameter is determined by an amount of thickness deformation of a force-bearing part of the light-emitting sublayer in a thickness direction of the light-emitting sublayer under unit force.

17. The display panel according to claim 16, wherein the compressibility parameter is calculated by the following formula:
X=ΔF/ΔH,
wherein ΔF is a difference between different forces in the thickness direction of the light-emitting sublayer, and ΔH is a thickness difference of the force-bearing part of the light-emitting sublayer under different forces.

18. The display panel according to claim 17, wherein the first threshold is −1.7, and the compressibility parameter of the light-emitting sublayer is less than 0.

19. The display panel according to claim 15, wherein when the display panel is powered on, a ratio of an amount of thickness expansion of the light-emitting sublayer to an original thickness of the light-emitting sublayer is less than or equal to 5%.

20. The display panel according to claim 15, wherein when the light-emitting sublayer is heated, a ratio of an amount of thickness expansion of the light-emitting sublayer to an original thickness of the light-emitting sublayer is less than or equal to 10%.
